(19) United States
(12) Patent Application Publication
(10) Pub. No.: US 2009/0289371 A1
(43) Pub. Date: Nov. 26, 2009

(54) SWITCHING ELEMENT AND METHOD OF MANUFACTURING THE SAME

(75) Inventor: Toshitsugu Sakamoto, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 12/097,468

(22) PCT Filed: Dec. 15, 2006
(86) PCT No.: PCT/JP2006/325050

§ 371 Date: Jun. 13, 2008

(30) Foreign Application Priority Data
Dec. 15, 2005 (JP) 2005-361826

(51) Int. Cl. H01L 49/00; H01L 27/10; H01L 21/02

(52) U.S. Cl. 257/773; 438/666; 438/610; 257/E27.07; 257/E21.002; 257/E23.01

(57) ABSTRACT

A switching element includes a first electrode, a second electrode, an ionic conductive portion and a buffer portion. The first electrode is configured to be available to feed metal ions. The ionic conductive portion is configured to contact the first electrode and the second electrode, and include an ionic conductor in which the metal ions are movable. The buffer portion is configured to have a smaller hardness than the ionic conductor, and be located between the first electrode and the second electrode along the ionic conductive portion. Electrical characteristics are switched by depositing or melting metal between said first electrode and said second electrode based on a potential difference between said first electrode and said second electrode.

### TECHNICAL FIELD

The present invention relates to a switching element utilizing electrochemical reaction and a method of manufacturing the same.

### BACKGROUND ART

For diversification of programmable logic functions and implementation of the functions in electronics, it is required to make size of a switching element connecting logic cells to each other smaller and make on-resistance of the switching element smaller. As a switching element which can satisfy such requirements, a switching element utilizing metal ion migration (hereinafter referred to as a metal-atom-migration switching element) in an ionic conductor (material in which ions can freely move around) as well as deposition and melting of metal due to electrochemical reaction has been proposed. As well known, the metal-atom-migration switching element has a smaller size and a smaller on-resistance than a semiconductor switching element (e.g. MOSFET) often used in the programmable logic. The metal-atom-migration switching element is classified into two-terminal and three-terminal types depending on the number of necessary electrodes, and into internal and surface types depending on the place where metal ions are deposited in the ionic conductor. Hereinafter, a structure and an operation of the internal type element among the typical metal-atom-migration switching element will be described.

FIGS. 1A and 1B are schematic sectional views showing structures of a two-terminal-internal type of the metal-atom-migration switching elements in a first conventional example (National publication 2002-536840 of translated version of PCT application: International Publication WO00/48196). The metal-atom-migration switching element includes an ionic conductive portion 410 formed of an ionic conductor (Cu₂S), a second electrode (Ti) 412 which is in contact with the ionic conductive portion 410 and a first electrode 411 which is in contact with the ionic conductive portion 410 and made of metal (Cu) as a source of metal ions (Cu+). Materials forming components in FIGS. 1A and 1B are only examples.

When a negative voltage is applied to the second electrode 412 using the first electrode 411 as a reference, metal ions (Cu+) in the vicinity of a contact surface between the ionic conductive portion 410 and the second electrode 412 are reduced and metal (Cu) is deposited in the contact surface between the ionic conductive portion 410 and the second electrode 412. In response to the deposition of the metal (Cu), the metal (Cu) of the first electrode 411 is oxidized and melts into the ionic conductive portion 410 in the form of metal ions (Cu+), so that positive ions and negative ions in the ionic conductive layer are kept in balance. The deposited metal (Cu) grows in the ionic conductive layer toward the first electrode 411. When the deposited metal (Cu) contacts the first electrode 411, the switching element is placed into a conductive (on) state (See FIG. 1A).

Conversely, when a positive voltage is applied to the second electrode 412 using the first electrode 411 as a reference, an opposite electrochemical reaction proceeds.

As a result, the deposited metal (Cu) does not contact first electrode 411 and thus, the switching element is placed into a disconnection (off) state (See FIG. 1B). As described above, metal atoms (Cu) forming the first electrode 411 as deposition substance migrates between the second electrode 412 and the first electrode 411 due to electrochemical reaction to form a metal line for electrically connecting the second electrode 412 to the first electrode 411 in the conductive (on) state.

Next, a second conventional example (Y. Hirose and H. Hirose, “Polarity-dependent memory switching and behavior of Ag dendrite in Ag-photodoped amorphous As₂S₃ films”, Journal of Applied Physics, (US), vol. 47, No. 6, June, 1976, p. 2767-2772) will be described. The second conventional example relates to another internal type element. FIGS. 2A and 2B are diagrams showing structures of a two-terminal-surface type of the metal-atom-migration switching element in the second conventional example. FIG. 2A is a schematic plan view (upper side) and a schematic sectional view (lower side) showing the structure. FIG. 2B is a plan microphotograph showing metal deposited on an electrode.

As shown in FIG. 2A, the metal-atom-migration switching element includes an ionic conductive layer 420 formed of an ionic conductor (Ag-doped As₂S₃), an Au electrode 422 made of metal (Au) which is in contact with the ionic conductive layer 420 and an Ag electrode 421 made of metal (Ag) which is in contact with the ionic conductive layer 420 and serves as a source of metal ions (Ag+). The ionic conductive layer 420 is formed on a slide glass 425.

When a negative voltage is applied to the Au electrode 422 and a positive voltage is applied to the Ag electrode 421, as in the first conventional example, metal ions (Ag+) in the vicinity of a contact surface between the ionic conductive layer 420 and the Au electrode 422 are reduced and metal (Ag) is deposited on the contact surface between the ionic conductive layer 420 and the Au electrode 422. The deposited metal (Ag) grows on the surface of the ionic conductive layer toward the Ag electrode 421 (FIG. 2B) and contacts the Ag electrode 421. At this time, there is continuity between the Ag electrode 421 and the Au electrode 422 (on state). When reverse voltages are applied, a part of the deposited metal is disconnected, leading to the off-state.

A third conventional example will be described. The third conventional example relates to still another internal type element. FIG. 3 is a schematic sectional view showing a structure of a three-terminal-internal type of the metal-atom-migration switching element as the third conventional example (International Publication WO2005/008783). The metal-atom-migration switching element includes an ionic conductive layer 430 formed of an ionic conductor (Cu₂S), a second electrode (Ti) 432 which is in contact with the ionic conductive layer 430, a first electrode 431 which is in contact with the ionic conductive layer 430 and made of metal (Cu) as a source of metal ions (Cu+) and a third electrode 433 which is in contact with the ionic conductive layer 430 and made of metal (Cu) as a source of metal ions (Cu+). The third electrode 433 is formed on a substrate 435. Materials forming components in FIG. 3 are only examples.

Arrangement of the above-mentioned three electrodes will be described. As shown in FIG. 3, the first electrode 431 and the second electrode 432 are arranged on a same plane of the ionic conductive layer 430. A distance between the third electrode 433 and the first electrode 431 is equal to a distance between the third electrode 433 and the second electrode 432, which is determined by a thickness of the ionic conductive layer 430. A distance between the first electrode 431 and the second electrode 432 is smaller than a thickness of the ionic conductive layer 430.

When a positive voltage is applied to the third electrode 433 using the second electrode 432 as a reference, metal ions (Cu+) in the vicinity of a contact surface between the ionic conductive layer 430 and the second electrode 432 are reduced and metal (Cu) is deposited on the contact surface between the ionic conductive layer 430 and the second electrode 432. In response to the deposition of metal (Cu), the metal (Cu) on the third electrode 433 is oxidized and melts into the ionic conductive layer 430 in the form of metal ions (Cu+), so that positive and negative ions in the ionic conductive layer are kept in balance. The deposited metal (Cu) grows on the surface of the ionic conductive layer. When the deposited metal (Cu) contacts the first electrode 431, the switching element is placed into a conductive (on) state. Conversely, when a negative voltage is applied to the third electrode 433 using the second electrode 432 as a reference, a reverse electrochemical reaction proceeds. As a result, the deposited metal (Cu) does not contact the first electrode 431 and thus, the switching element is placed into a disconnection (off) state.

As described above, the metal atoms (Cu) forming the third electrode 433 migrates between the second electrode 432 and the first electrode 431 as deposition substance due to electrochemical reaction to form a metal line for electrically connecting the second electrode 432 to the first electrode 431 in the conductive (on) state.

Next, a fourth conventional example will be described. The fourth conventional example relates to a surface-type element. FIG. 4 is a schematic sectional view showing a structure of a metal-atom-migration switching element applicable as a surface-type element in the fourth conventional example (U.S. Pat. No. 6,825,489B2). As shown in FIG. 4, the metal-atom-migration switching element includes a lower electrode 441, an ionic conductor 440 provided on a side wall of an opening 450 of an insulating film 444 formed on a lower electrode and an upper electrode 442 formed on the insulating film. The upper electrode 442 is in contact with an upper surface of the ionic conductor 440. Also in this structure, the element can be switched on or off using the method similar to that in the third conventional example.

As related technique, Japanese Laid-Open Patent Application JP-P 2002-76325A discloses an electronic element capable of controlling conductance. This electronic element is formed of a first electrode made of a mixed conductor having ionic conductivity and electronic conductivity and a second electrode made of a conductive material and can control conductance between the electrodes.

As related technique, Japanese Laid-Open Patent Application JP-P 2005-101535A discloses a semiconductor device. The semiconductor device includes a first and a second wiring layers which are different from each other and a via which connects a wiring of the first wiring layer to a wiring of the second wiring layer and contains a member of variable conductivity. The via forms a conductivity-variable switch element having a first terminal as a contact portion between the via and the first wiring layer and a second terminal as a contact portion between the via and the second wiring layer. A connection state between the first terminal and the second terminal in the switch element can be variably set to a short-circuit state, an opened state or an interim state between the short-circuit and the opened state.

As related technique, Japanese Laid-Open Patent Application JP-A-Heisei 06-224412 discloses atomic switch circuit and system. The atomic switch circuit includes means adapted to vary conductivity of an atomic fine wire formed of a plurality of atoms by migrating certain atoms in the atomic fine wire, and has an information storage function or a logic function, wherein the plurality of atoms forming the atomic fine wire is arranged so that electrons of the atom interact to those of the other atoms.

In a case of the internal-type element, when one attempts to deposit metal in the ionic conductive layer, since deposit amount is limited due to structural stress, it is difficult to form a thick metal bridge between electrodes. A thickness of a metal bridge in the first conventional example is a few nanometers. On the other hand, when the internal-type element is used in a LSI (Large Scale Integrated Circuit), it is desired that the thickness of the metal bridge is as thick as possible in a switch-on state. This is due to that the metal atoms migrates (electromigration) due to flow of electrons at the time of switch-on, thereby possibly breaking the metal bridge. On the contrary, in a case of the surface-type element, since metal is deposited in space within the opening as shown in FIG. 4 at the time of switch-on, the ionic conductive layer is not subjected to structural stress and a thick bridge (having a diameter of 10 nm or more) can be formed.

The structure in FIG. 4 is the sectional view of the surface-type element under manufacturing. To integrate the surface-type element into the LSI, when upper layers such as a wiring layer and a protective film are formed on the upper electrode, since the surface of the ionic conductive layer is exposed on the side of the opening, the cavity in the opening is filled with the upper layers. When one attempts to deposit metal between the electrodes in the state where the cavity is filled with upper layers, structural stress occurs in the ionic conductive layer.

### DISCLOSURE OF INVENTION

An object of the present invention is to provide a switching element in which structural stress caused inside at the time of turn-on is relieved and a method of manufacturing the switching element.

Another object of the present invention is to provide a switching element capable of more stabilizing an on-state of the switch and a method of manufacturing the switching element.

In order to achieve the above-mentioned object, the switching element according to the present invention includes a first electrode, a second electrode, an ionic conductive portion and a buffer portion. The first electrode is configured to be available to feed metal ions. The ionic conductive portion is configured to contact the first electrode and the second electrode, and include an ionic conductor in which the metal ions are movable. The buffer portion is configured to have a smaller hardness than the ionic conductor, and be located between the first electrode and the second electrode along the ionic conductive portion. Electrical characteristics are switched by depositing or melting metal between said first electrode and said second electrode based on a potential difference between said first electrode and said second electrode.

In the above-mentioned switching element, the buffer portion may include a porous material. In the above-mentioned switching element, the buffer portion may be a cavity.

The above-mentioned switching element may further include an insulating film configured to have an opening which reaches the first electrode and the second electrode between the first electrode and the second electrode. The ionic conductive portion may be located on a side wall of the opening.

In the above-mentioned switching element, the second electrode may be disposed on a substrate. The ionic conductive portion and the buffer portion may be disposed on the second electrode, and the first electrode may be disposed on the ionic conductive portion and the buffer portion.

The above-mentioned switching element may further include a third electrode configured to contact the ionic conductive portion, and be available to feed metal ions. Electrical characteristics are switched by depositing or melting metal between said first electrode and said second electrode based on a potential difference among said first electrode, said second electrode and said third electrode.

In the above-mentioned switching element, the first electrode and the third electrode are provided on a same plane. An insulating film having an opening may be provided among the first electrode, the third electrode and the second electrode, wherein the opening reaches these three electrodes. The ionic conductive portion may be disposed on a side wall of the opening.

In the above-mentioned switching element, the second electrode may be disposed on the substrate. The ionic conductive portion and the buffer portion may be disposed on the second electrode. The first electrode and the third electrode may be disposed on the ionic conductive portion and the buffer portion.

To achieve the above-mentioned objects, a manufacturing method of the switching element according to the present invention includes steps of (a) forming a second electrode on a substrate, (b) forming an opening, substantially vertically to the substrate and partially overlap the second electrode, in an interlayer insulating layer provided so as to cover the substrate and the second electrode, (c) forming an ionic conductor so as to cover a side wall of the opening, (d) filling a filling film on an inner side of the ionic conductor, and (e) forming a first electrode so as to cover the interlayer insulating layer, the ionic conductor and a part of the filling film.

The first electrode is available to feed metal ions. The ionic conductive portion includes the ionic conductor in which the metal ions are movable. The filling film has a smaller hardness than the ionic conductor.

The manufacturing method of the above-mentioned switching element may further has a step of (f) removing the filling film.

In the manufacturing method of the above-mentioned switching element, the step (e) may include a step (e1) forming apart from the first electrode so as to cover the interlayer insulating layer, the ionic conductor and a part of the filling film.

### BRIEF DESCRIPTION OF THE DRAWINGS

FIG. 1A is a schematic sectional view showing a structure of a metal-atom-migration switching element in a first conventional example;

FIG. 1B is a schematic sectional view showing a structure of the metal-atom-migration switching element in the first conventional example;

FIG. 2A is a schematic plan view and a schematic sectional view showing structures of metal-atom-migration switching elements in a second conventional example;

FIG. 2B is a plan microphotograph showing metal deposited on an electrode of the metal-atom-migration switching element in the second conventional example;

FIG. 3 is a schematic sectional view showing a structure of a metal-atom-migration switching element in a third conventional example;

FIG. 4 is a schematic sectional view showing a structure of a metal-atom-migration switching element in a fourth conventional example;

FIG. 5A is a perspective view showing one structure example of a basic two-terminal switch;

FIG. 5B is a schematic sectional view showing one structure example of the basic two-terminal switch;

FIG. 5C is a schematic sectional view showing another structure example of the basic two-terminal switch;

FIG. 6A is a schematic plan view showing one structure example of a two-terminal switch according to a first exemplary embodiment;

FIG. 6B is a schematic sectional view showing one structure example of the two-terminal switch according to the first exemplary embodiment;

FIG. 7A is a schematic sectional view showing a manufacturing method of the two-terminal switch according to the first exemplary embodiment;

FIG. 7B is a schematic sectional view showing a manufacturing method of the two-terminal switch according to the first exemplary embodiment;

FIG. 7C is a schematic sectional view showing a manufacturing method of the two-terminal switch according to the first exemplary embodiment;

FIG. 7D is a schematic sectional view showing a manufacturing method of the two-terminal switch according to the first exemplary embodiment;

FIG. 7E is a schematic sectional view showing a manufacturing method of the two-terminal switch according to the first exemplary embodiment;

FIG. 7F is a schematic sectional view showing a manufacturing method of the two-terminal switch according to the first exemplary embodiment;

FIG. 7G is a schematic sectional view showing a manufacturing method of the two-terminal switch according to the first exemplary embodiment;

FIG. 7H is a schematic sectional view showing a manufacturing method of the two-terminal switch according to the first exemplary embodiment;

FIG. 8A is a schematic plan view showing one structure example of a two-terminal switch according to a second exemplary embodiment;

FIG. 8B is a schematic plan view showing one structure example of the two-terminal switch according to the second exemplary embodiment;

FIG. 9A is a schematic plan view showing one structure example of a three-terminal switch according to a third exemplary embodiment;

FIG. 9B is a schematic plan view showing one structure example of the three-terminal switch according to the third exemplary embodiment;

FIG. 10A is a schematic plan view showing another structure example of the three-terminal switch according to the third exemplary embodiment; and

FIG. 10B is a schematic plan view showing another structure example of the three-terminal switch according to the third exemplary embodiment.

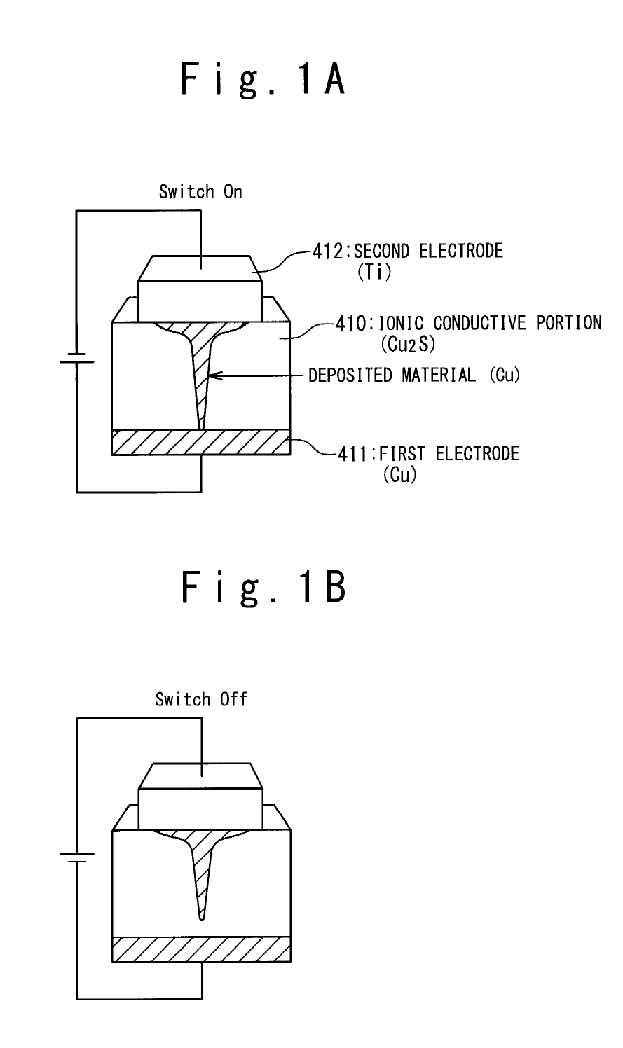

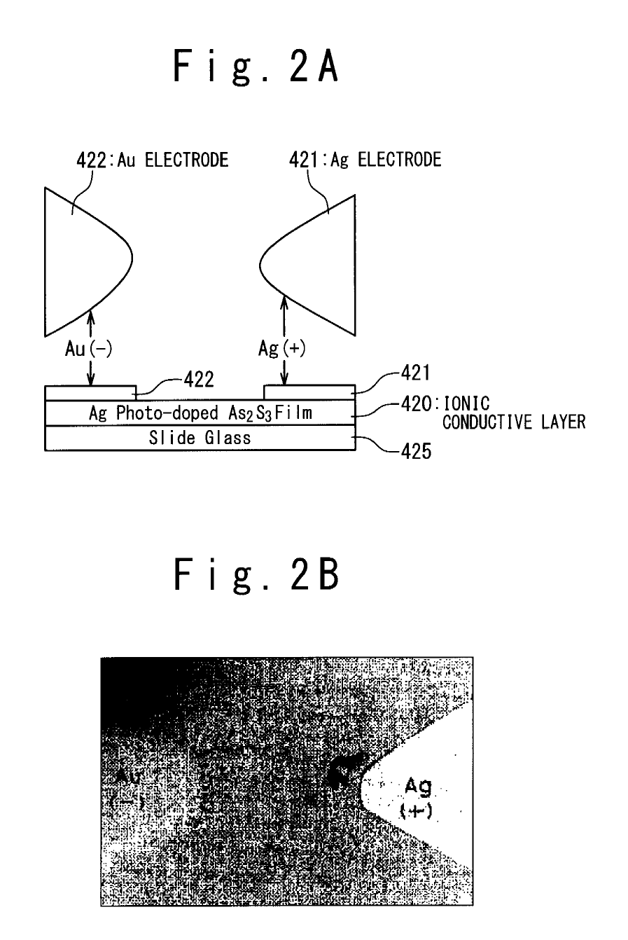

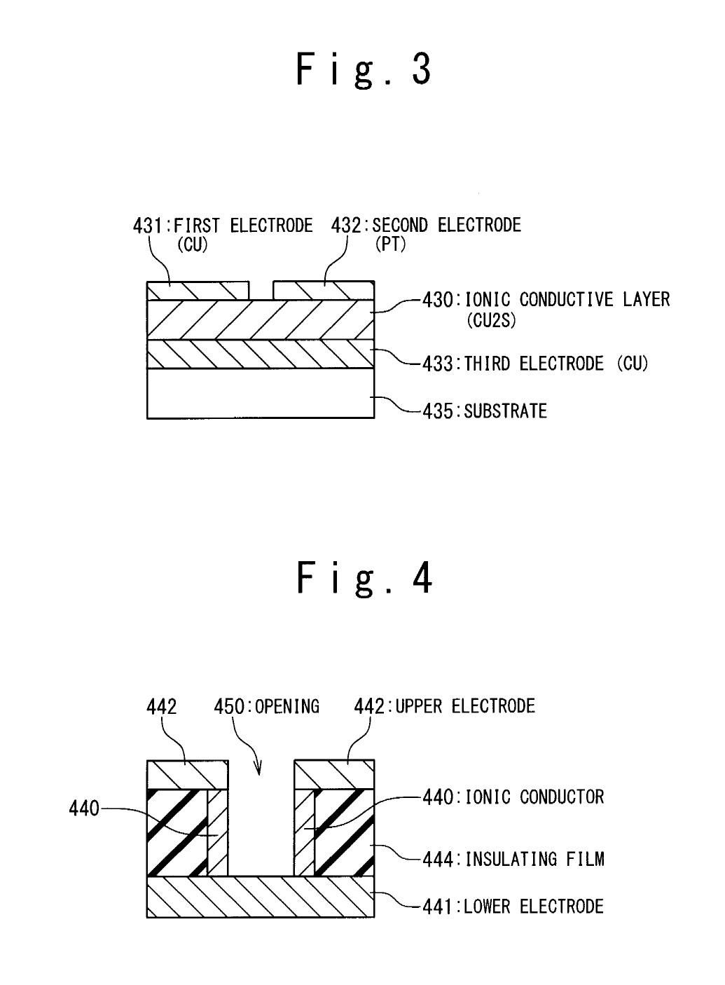

### BEST MODE FOR CARRYING OUT THE INVENTION

A switching element according to the present invention is characterized in that a buffer portion for buffering structural stress generated when metal is deposited is provided along an ionic conductor.

First, a basic structure and operational principle of a two-terminal type and a three-terminal type metal-atom-migration switching elements according to the present invention will be described using the two-terminal type as an example. Hereinafter, the two-terminal type metal-atom-migration switching element is referred to as a two-terminal switch and the three-terminal type metal-atom-migration switching element is referred to as a three-terminal switch.

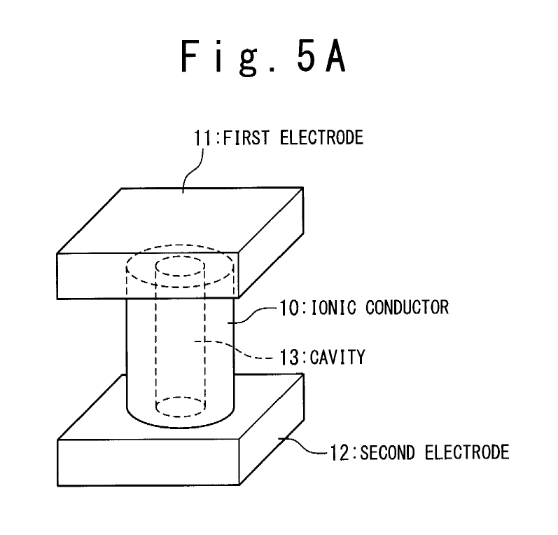

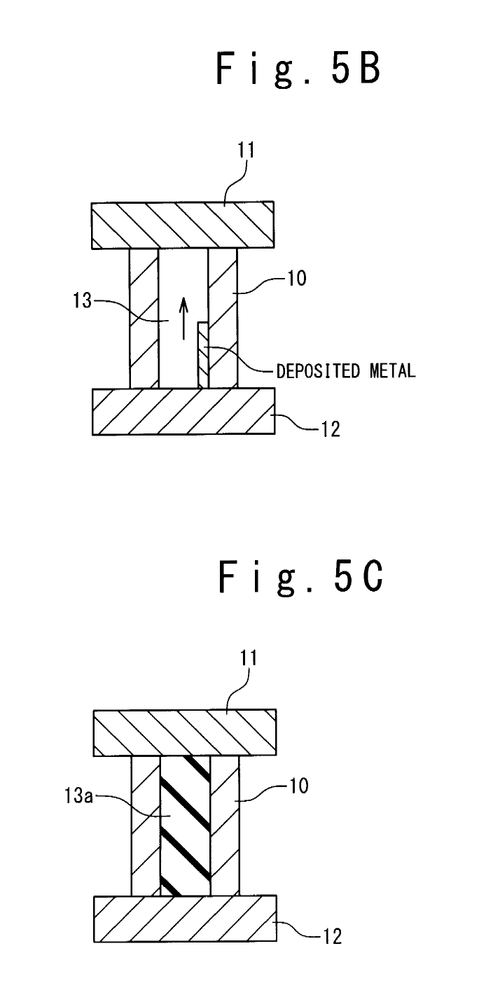

FIGS. 5A and 5B are a perspective view and a schematic sectional view showing one structure example of the two-terminal switch according to the present invention.

As shown in FIG. 5A, the two-terminal switch includes an ionic conductor 10 which forms a cavity 13 therein, and a first electrode 11 and a second electrode 12 which are located both ends of the ionic conductor 10, respectively, and are in contact with the cavity 13.

An operation of the two-terminal switch shown in FIGS. 5A and 5B will be described.

When a negative voltage is applied to the second electrode 12 using the first electrode 11 as a reference, metal ions in the vicinity of a contact surface between the ionic conductor 10 and the second electrode 12 are reduced and metal is deposited on the contact surface between the ionic conductor 10 and the second electrode 12. The metal is deposited mainly not within the ionic conductor but on a surface of the ionic conductor on a side of the cavity 13, which has less structural stress. In response to the deposition of the metal, the metal of the first electrode 11 is oxidized and melts into the ionic conductor 10 in the form of metal ions, so that positive and negative ions in the ionic conductor are kept in balance. The deposited metal grows the surface of the ionic conductor toward the first electrode 11. When the deposited metal contacts the first electrode 11, the switching element is placed into the conductive (on) state.

Conversely, when a positive voltage is applied to the second electrode 12 using the first electrode 11 as a reference, reverse electrochemical reaction proceeds. As a result, the deposited metal melts into the ionic conductor 10, and the metal which extends from the second electrode 12 and then contacts the first electrode 11 is broken, so that the switching element is placed into a disconnection (off) state. Even before electrical connection is completely broken, electrical characteristics vary, for example, a resistance between the first electrode 11 and the second electrode 12 becomes larger and inter-electrode capacitance varies, and finally, electrical connection is broken.

As described above, due to positive or negative potential difference between the first electrode 11 and the second electrode 12, the metal atoms forming the first electrode 11 migrate between the first electrode 11 and the second electrode 12 as deposition substance by electrochemical reaction to form a metal line for electrically connecting the first electrode 11 to the second electrode 12 in a conductive (on) state.

Chalcogenide as a compound containing a chalcogen element and halogenide as a compound containing a halogen element can be adopted as a material contained in the ionic conductor 10. The chalcogen elements are oxygen, sulfur, selenium, tellurium and polonium. The halogen elements are fluorine, chlorine, bromine, iodine and astatine. Chalcogenide and halogenide include materials having a high metal ion conductivity (copper sulfide, silver sulfide, silver telluride, rubidium copper chloride, silver iodide, copper iodide, etc.) and materials having a low ion conductivity (tantalum oxide, silicon oxide, tungsten oxide, alumina, etc.).

Materials for the first electrode 11 include copper and silver. When the first electrode 11 is made of silver, metal ions are silver ions. With respect to the materials for the first electrode 11, barrier metal (W, Ta, TaN, Ti, TiN, etc.) can be adopted as materials for the second electrode 12. When the ionic conductor 10 is made of copper sulfide, the first electrode 11 is made of copper and the second electrode 12 is made of Ti, the metal ions are copper ions.

As described above, according to the present invention, to relieve structural stress, a buffer portion which contacts the ionic conductor 10 is provided. The buffer portion is made of a material to which metal is deposited more easily than an inside of the ionic conductor 10. Such material is, for example, a material having a lower hardness than the ionic conductor 10, such as air filled in the cavity. That is, for example, the cavity 13 is provided as the buffer portion. Thereby, since metal is deposited in the space within the cavity 13, it is possible to deposit metal without any structural stress applied to the ionic conductor 10. Thus, a thicker bridge can be formed, thereby more stabilizing the on-state.

Even when the cavity 13 as the buffer portion is filled with a soft material 13a having a lower hardness than the ionic conductor 10 as shown in FIG. 5C, metal can be easily deposited. This is due to that since the soft material absorbs change in shape caused by the deposition of the metal, structural stress applied to the ionic conductor 10 can be relieved. Here, the soft material includes elastic materials. The elastic materials include synthetic resin and synthetic rubber.

Furthermore, the material filled in the cavity may be porous materials having holes therein in addition to the soft material. The porous materials include methylsiloxane (formed of silicon, carbon, oxygen). Methylsiloxane is a material formed by adding methyl group (CH—) to silicon oxide and has holes of a few nm around the methyl group.

### First Exemplary Embodiment

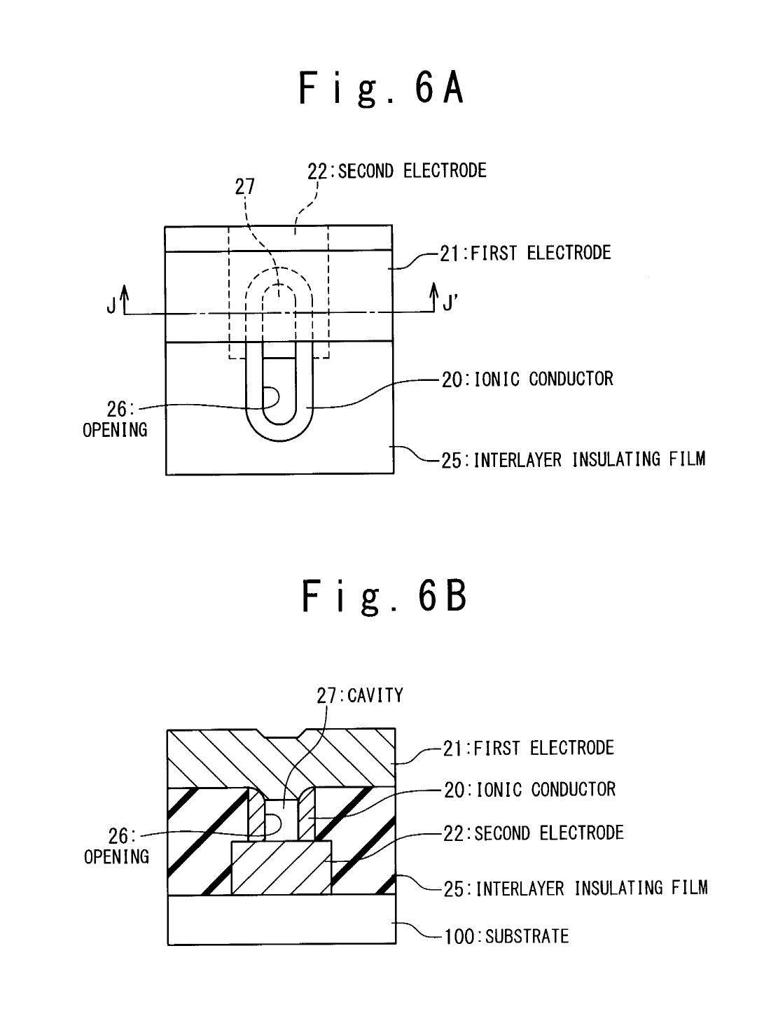

The present exemplary embodiment will be described. FIGS. 6A and 6B are a schematic plan view and a schematic sectional view showing one structure example of a two-terminal switch according to the present exemplary embodiment, respectively. FIG. 6B (sectional view) shows a cross section taken along JJ′ in FIG. 6A (plan view).

As shown in FIGS. 6A and 6B, the two-terminal switch includes a second electrode 22 on a substrate 100, an interlayer insulating film 25 on which an opening 26 is formed so that a part of the second electrode 22 may be exposed, an ionic conductor 20 formed on a side wall of the opening 26 and a first electrode 21 provided so as to cover a part of the opening 26. The first electrode 21 is made of copper and the second electrode 22 is made of platinum. The ionic conductor 20 is made of copper sulfide and the interlayer insulating film 25 is made of silicone oxide film.

As shown in a plan view of FIG. 6A, about half of a pattern of the opening 26 covers the second electrode 22. An area of the first electrode 21 which covers the opening 26 is located above the second electrode 22. Of the opening 26 whose side wall is the ionic conductor 20, a space sandwiched between the first electrode 21 and the second electrode 22 becomes the cavity 27 for metal deposition as shown in FIG. 6B.

Compared with a case where the whole between the first electrode 21 and the second electrode 22 is formed of the film of the ionic conductor 20, by providing the ionic conductor 20 only on the side wall of the opening 26, stress generated at the time of metal deposition can be diffused to a side of the interlayer insulating film 25 as well as the cavity 27. That is, metal can be deposited without any structural stress applied to the ionic conductor 20, thereby more stabilizing an on-state.

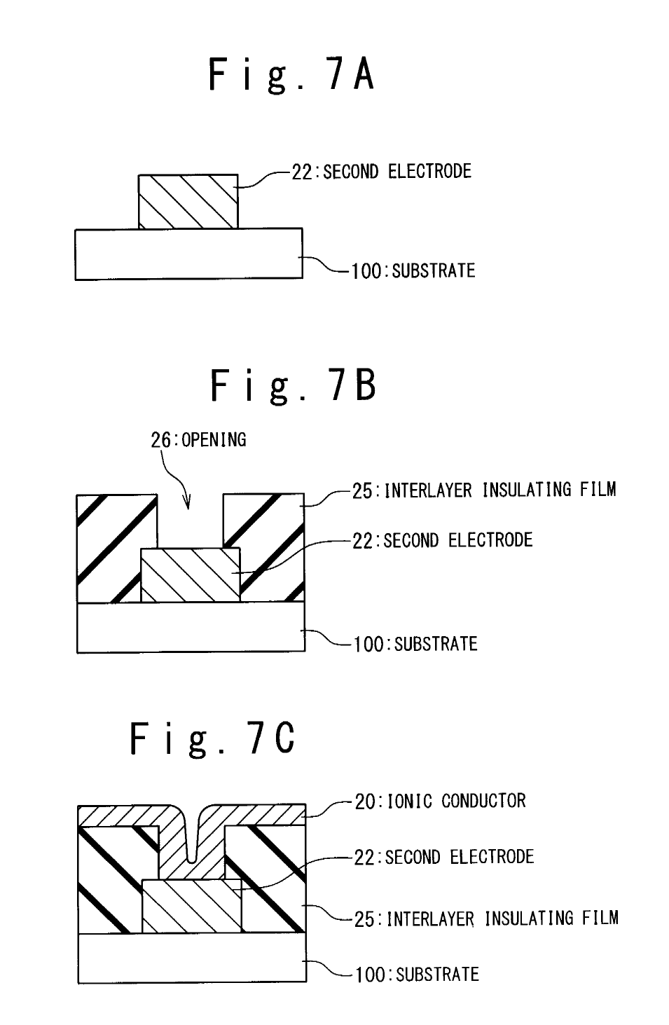

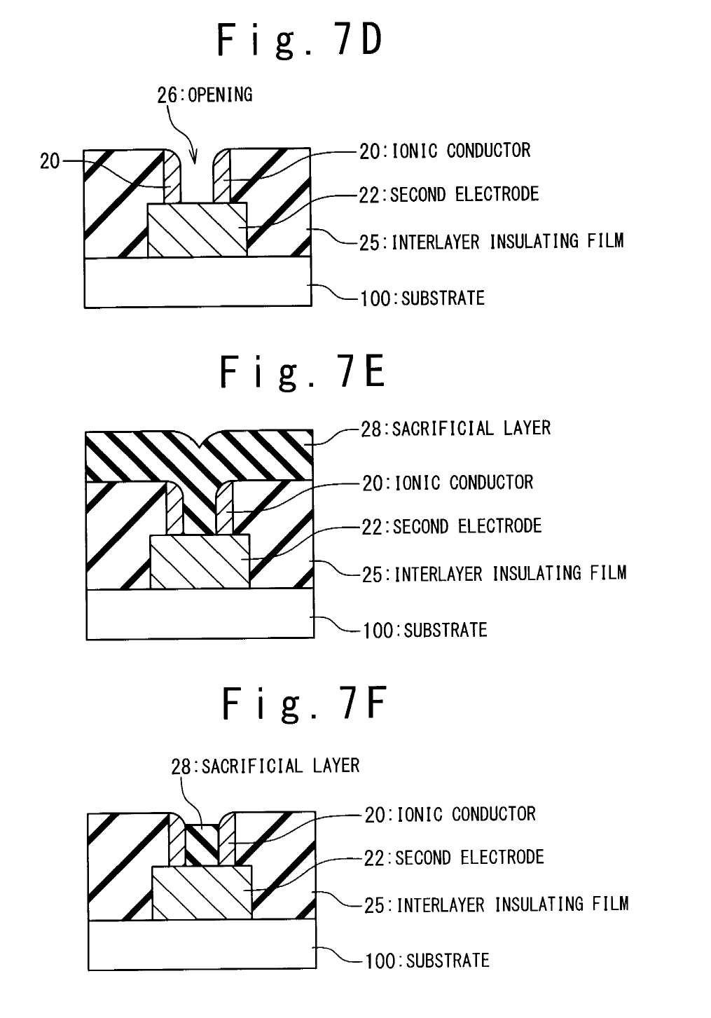

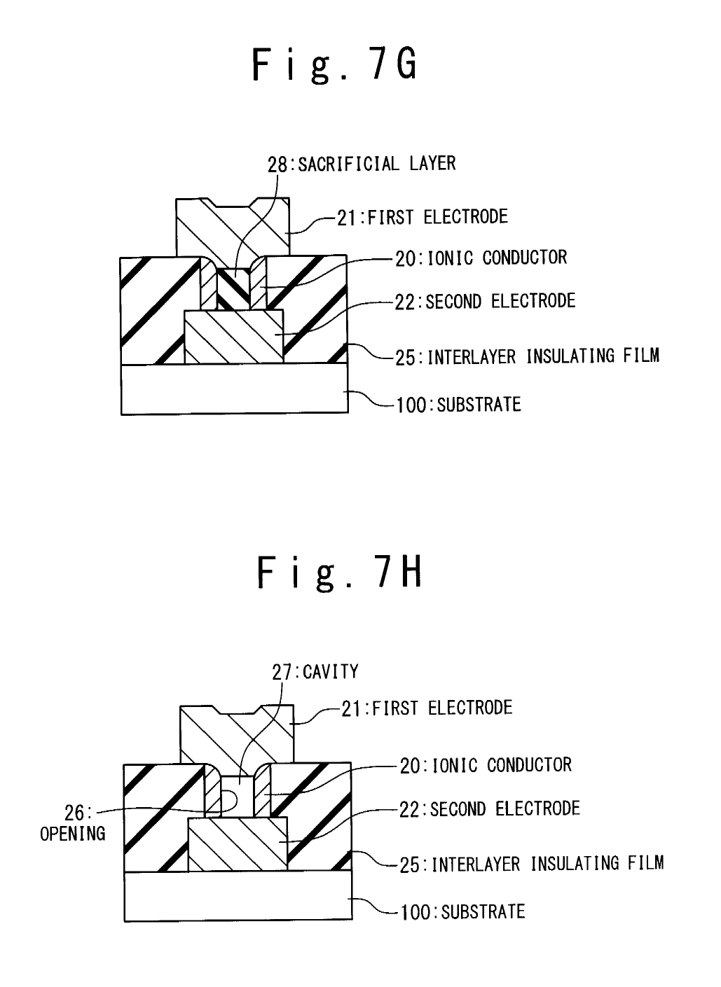

Next, a manufacturing method of the two-terminal switch shown in FIGS. 6A and 6B will be described. FIGS. 7A to 7H are schematic sectional views showing the manufacturing method of the two-terminal switch according to the present exemplary embodiment.

A silicone oxide film having a thickness of 300 nm is formed on a surface of a silicon substrate to constitute the substrate 100. Using the conventional lithography technique, a resist pattern is formed on an area of the substrate 100 where the second electrode 22 is not formed. Subsequently, a platinum having a thickness of 100 nm is formed on the resist pattern according to a vacuum evaporation method. After that, the resist pattern and platinum formed on the resist pattern are removed according to lift-off technique and then, as shown in FIG. 7A, remaining platinum is formed as the second electrode 22. At this time, given that a length of the second electrode 22 in the horizontal direction in FIG. 7A is a width, the width of the second electrode 22 is set to be larger than 100 nm. The length of the second electrode 22 in the depth direction in FIG. 7A is set to be larger than 150 nm.

Next, a silicone oxide film having a thickness of 300 nm is formed as the interlayer insulating film 25 so as to cover the second electrode 22 and an exposed part of an upper surface of the substrate. Subsequently, a resist pattern for forming the opening 26 is formed on the interlayer insulating film 25 according to conventional lithography technique. At this time, when viewing the surface of the substrate from vertically upwards, an opening provided on the resist pattern covers a part of the pattern of the second electrode 22. The resist pattern on the interlayer insulating film 25 is etched by reactive chemical etching until an upper surface of the second electrode 22 is exposed. After that, the resist pattern is removed. In this manner, as shown in FIG. 7B, the opening 26 is formed. The opening 26 is set to have a width of 100 nm as a length in a horizontal direction in FIG. 7B and a length of 300 nm in a depth direction in FIG. 7B. The depth of the opening 26 is 200 to 300 nm. The opening 26 overlaps the pattern on the second electrode 22 by 150 nm in the depth direction in FIG. 7B.

Subsequently, as shown in FIG. 7C, copper sulfide as the ionic conductor 20 is formed so as to cover an upper surface of the interlayer insulating film 25 and the opening 26 and have a uniform thickness according to a sputtering method. Subsequently, the ionic conductor 20 is anisotropically etched according to a reactive ion etching method to remove copper sulfide on the interlayer insulating film 25 and a bottom surface of the opening 26 (FIG. 7D). Since etching speed on the side wall of the opening 26 is lower than that on the bottom surface of the opening 26, a part of the ionic conductor 20 remains unetched.

After that, as shown in FIG. 7E, an LOR resist (made by Dow Corning Corporation) having a thickness of about 200 nm as a sacrificial layer is prepared by the spin coating method. Since an organic solvent containing resin such as the LOR resist has a low viscosity, even when a substrate has a large step or a deep opening, the solvent fills the step or the opening and a surface becomes substantially flat. For this reason, a thickness of the sacrificial layer 28 formed by the spin coating method in the opening 26 is larger than that on the interlayer insulating film 25. Subsequently, when the sacrificial layer 28 is isotropically etched by using remover liquid, as shown in FIG. 7F, the sacrificial layer 28 on the interlayer insulating film 25 is removed except for the sacrificial layer 28 accumulated in the opening 26. Since the thickness of the sacrificial layer 28 in the opening 26 is larger than that on the interlayer insulating film 25 and an etching rate of the sacrificial film 28 in the opening 26 is lower than that on the interlayer insulating film 25, the sacrificial layer 28 in the opening 26 can be left.

Next, as in the method of forming the second electrode 22, a resist pattern is formed on an area where the first electrode 21 is not formed and copper having a thickness of 100 nm is formed on the resist pattern according to the vacuum evaporation method. At this time, since the sacrificial film 28 is filled in the opening 26, copper can be formed also on the opening 26 via the sacrificial film 28. Subsequently, the resist pattern and the copper formed on the resist pattern are removed according to lift-off technique and remaining copper is formed as the first electrode 21 (FIG. 7G). After formation of the first electrode, as shown in FIG. 6A, a part of the opening 26 is exposed without being covered with the first electrode 21. Then, when soaking in remover liquid, the release liquid enters into the cavity 27 between the first electrode 21 and the second electrode 22 from the exposed area of the opening 26 and as shown in FIG. 7H, all the sacrificial layer 28 is removed from the opening 26.

According to the manufacturing method of the two-terminal switch according to the present exemplary embodiment, since the sacrificial layer 28 is filled in the opening 26 when the copper is formed as the first electrode 21, the copper can be formed substantially flat also on the cavity 27 formed by removing the sacrificial layer 28 later. After formation of the first electrode, a part of the opening 26 is exposed and the sacrificial layer 28 is isotropically etched by using remover liquid. Thus, by removing the sacrificial layer 28 covered with the first electrode 21, the cavity 27 can be formed between the first electrode 21 and the second electrode 22.

As long as the sacrificial layer 28 can be formed according to the spin coating method and removed by isotropic etching method, materials other than the above-mentioned material may be adopted without limiting the above-mentioned material.

The conventional internal-type element has a problem that structural stress is applied to the ionic conductor by volume expansion due to metal deposition. The conventional surface-type element has a problem how to form space itself although structural stress is reduced as compared with the internal-type element. U.S. Pat. No. 6,825,489 does not disclose a method of forming an upper layer while leaving a cavity, and thus, it is difficult to apply the elements in the fourth conventional example to the LSI as they are. According to the above-mentioned method, the surface-type switching element in the present exemplary embodiment can be integrated into the LSI with the cavity which relieves stress being left. As a result, metal can be deposited without any structural stress applied to the ionic conductor 20. Consequently, a thicker bridge can be formed, thereby more stabilizing the on-state.

Furthermore, with the structure where the second electrode 22, the ionic conductor 20 and the cavity 27, and the first electrode 21 are vertically formed on the substrate 100 in this order, an area occupied on the plane can be reduced. For this reason, it is more advantageous for the integration of LSI.

Furthermore, the sacrificial layer 28 can be used as the soft material without performing the step described referring to FIG. 7H. Since the sacrificial layer 28 is softer than the ionic conductor 20, the sacrificial layer 28 can absorb change in shape caused by the deposition of the metal. Thus, structural stress applied to the ionic conductor 20 can be reduced and a thicker bridge can be formed, thereby more stabilizing the on-state.

### Second Exemplary Embodiment

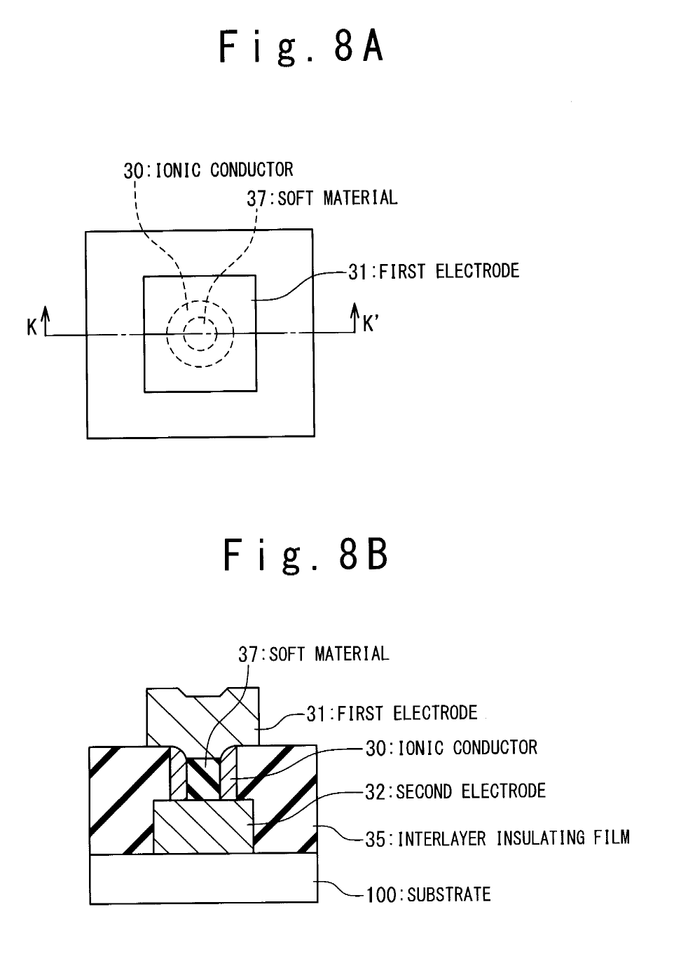

FIGS. 8A and 8B are a schematic plan view and a schematic sectional view showing one structure example of a two-terminal switch according to the present exemplary embodiment, respectively. FIG. 8B (sectional view) shows a cross section taken along KK′ in FIG. 8A (plan view).

As shown in FIGS. 8A and 8B, the two-terminal switch includes a second electrode 32 on the substrate 100, an interlayer insulating film 35 on which an opening is formed so that a part of the second electrode 32 is exposed, an ionic conductor 30 formed on a side wall of the opening and a first electrode 31 provided so as to cover the opening. The first electrode 31 is made of copper and the second electrode 32 is made of platinum. The ionic conductor 30 is made of copper sulfide and the interlayer insulating film 35 is formed of a silicone oxide film.

In the present exemplary embodiment, as shown in FIG. 8A, a soft material 37 is filled in the opening having the ionic conductor 30 as a side wall. An upper surface of the soft material 37 filled in the opening is covered with the first electrode 31. As distinct from the first exemplary embodiment, a pattern of the first electrode 31 is the substantially same as that of the second electrode 32 and thus, as shown in the plan view of FIG. 8A, these patterns are seemed to overlap with each other. As long as the ionic conductor 30 and the soft material 37 are sandwiched between the first electrode 31 and the second electrode 32, these two electrode patterns are not necessarily the same.

Since the soft material 37 is softer than the ionic conductor 30, the soft material can absorb change in shape caused by the deposition of the metal. Thus, structural stress applied to the ionic conductor 30 can be reduced and a thicker bridge can be formed, thereby more stabilizing the on-state.

Here, as described above, the soft material 37 refers to a material having a lower hardness than the ionic conductor 30. For example, the LOR resist in the first exemplary embodiment can be adopted.

Next, a manufacturing method of the two-terminal switch shown in FIGS. 8A and 8B will be described.

Detailed description of the same step as those in the first exemplary embodiment will be omitted. The sacrificial layer 28 shown in the first exemplary embodiment is used as the soft material 37.

In the step described with reference to FIG. 7B, an opening having a width of 100 nm as a length in a horizontal direction and a length of 100 nm in a depth direction in this figure is formed on the second electrode 32. A pattern of the opening falls within a pattern of the second electrode 32. When the first electrode 31 is formed in the step described with reference to FIG. 7G, the first electrode 31 covers upper surfaces of the soft material 37 filled in the opening and the ionic conductor 30. In the present exemplary embodiment, the step described with reference to FIG. 7H is not performed. In this manner, by adding the above-mentioned changes to the manufacturing method in the first exemplary embodiment, the two-terminal switch according to the present exemplary embodiment can be manufactured.

By using the two-terminal switch in the present exemplary embodiment, the same effects as those in the first exemplary embodiment can be obtained and in addition, an area on the plane can be further reduced. Furthermore, since the soft material 37 which serves as the buffer portion is filled in the opening, the first electrode 31 which covers the soft material 37 can be formed more flatly.

### Third Exemplary Embodiment

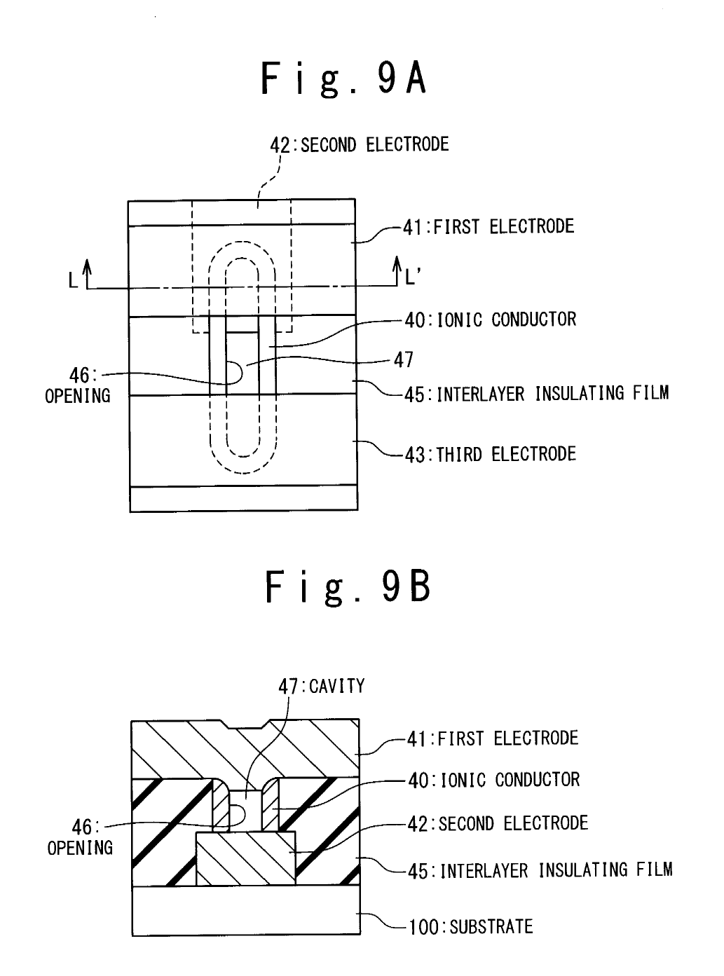

FIGS. 9A and 9B are a schematic plan view and a schematic sectional view showing one structure example of a three-terminal switch according to the present exemplary embodiment, respectively. FIG. 9B (sectional view) shows a cross section taken along LL′ in FIG. 9A (plan view).

As shown in FIGS. 9A and 9B, the three-terminal switch includes a second electrode 42 on the substrate 100, an interlayer insulating film 45 on which an opening 46 is formed so that a part of the second electrode 42 is exposed, an ionic conductor 40 formed on a side wall of the opening 46, a first electrode 41 provided immediately above the second electrode 42 so as to cover a part of the opening 46 and a third electrode 43 provided so as to cover a part of the opening 46. The first electrode 41 and the third electrode 43 are made of copper and the second electrode 42 is made of platinum. The ionic conductor 40 is made of copper sulfide and the interlayer insulating film 45 is formed of a silicone oxide film. A cavity 47 is provided in the opening 46 having the ionic conductor 40 as the side wall.

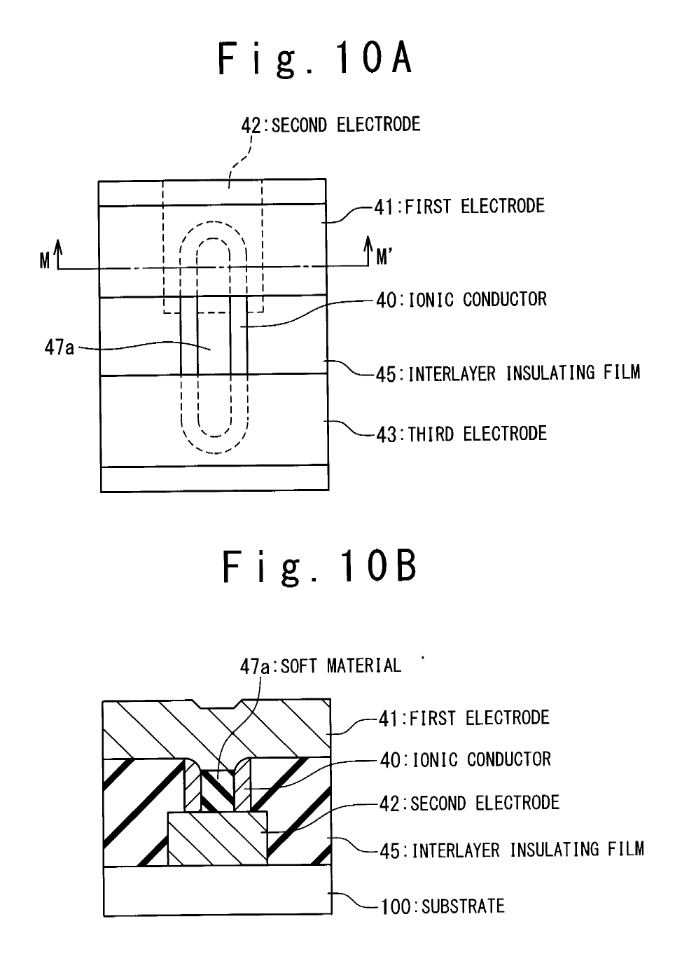

As described in the first and second exemplary embodiments, a soft material as a buffer portion may be filled in the cavity 47 as the buffer portion. FIGS. 10A and 10B are a schematic plan view and a schematic sectional view showing another structure example of a three-terminal switch according to the present exemplary embodiment, respectively. FIG. 10B (sectional view) shows a cross section taken along MM′ in FIG. 10A (plan view). As shown in FIGS. 10A and 10B, a soft material 47a is filled in the cavity. As the soft material, for example, the LOR resist in the first exemplary embodiment can be adopted. A porous material may be used as the soft material.

Since the soft material is softer than the ionic conductor 40, the soft material can absorb change in shape caused by the deposition of the metal. Thus, structural stress applied to the ionic conductor 40 can be reduced and a thicker bridge can be formed, thereby more stabilizing the on-state.

Next, an operation of the three-terminal switch shown in FIGS. 9A and 9B will be described.

When the first electrode 41 and the third electrode 43 are grounded and a negative voltage is applied to the second electrode 42, copper of the first electrode 41 becomes copper ions and the ions melt into the ionic conductor 40. The copper ions in the ionic conductor are deposited on the surfaces of the first electrode 41 and the second electrode 42, and the deposited copper forms a metal bridge for connecting the first electrode 41 to the second electrode 42. By electrically connecting the first electrode 41 to the second electrode 42 via the metal bridge, the three-terminal switch is placed into an on-state.

On the other hand, in the above-mentioned on-state, when the second electrode 42 is grounded and a negative voltage is applied to the third electrode 43, copper of the metal bridge melts into the ionic conductor 40 and a part of the metal bridge is broken. As a result, electrical connection between the first electrode 41 and the second electrode 42 is broken and the three-terminal switch is placed into the off-state. Even before electrical connection is completely broken, electrical characteristics vary, for example, a resistance between the first electrode 41 and the second electrode 42 becomes larger and inter-electrode capacitance varies, and finally, electrical connection is broken.

To turn the off-state into the on-state, a positive voltage may be applied to the third electrode 43. Thereby, copper of the third electrode 43 becomes copper ions and the ions melt into the ionic conductor 40. Then, the copper ions melted into the ionic conductor 40 are deposited on a broken part of the metal bridge as copper and the metal bridge electrically connects the first electrode 41 to the second electrode 42.

As described above, depending on the positive or negative potential difference among the first electrode 41, the second electrode 42 and the third electrode 43, the on-state and the off-state can be controlled.

Next, a manufacturing method of the three-terminal switch shown in FIGS. 9A and 9B will be described. Detailed description of the same step as those in the first exemplary embodiment will be omitted.

In a step described with reference to FIG. 7B, the opening 46 having a width of 100 nm as a length in the horizontal direction and a length of 500 nm in a depth direction in this figure is formed. When the first electrode 41 is formed in the step described with reference to FIG. 7G, the third electrode 43 is also formed at the same time. In a case where the soft material is filled in the cavity 47, the step described with reference to FIG. 7H is not performed. In this manner, by adding the above-mentioned changes to the manufacturing method in the first exemplary embodiment, the three-terminal switch according to the present exemplary embodiment can be manufactured.

Even the three-terminal switch having the third electrode 43 for on/off control can be integrated into the LSI with the cavity being left, and as in the First exemplary embodiment, can obtain the effect of relieving structural stress generated due to metal deposition.

Furthermore, with a structure where the second electrode 42, the ionic conductor 40 and the cavity 47, and the first electrode 41 and the third electrode 43 are vertically formed on the substrate 100 in this order, an area occupied on the plane can be reduced. For this reason, it is more advantageous for the integration of LSI.

Compared with a case where the whole between the first electrode 41 and the second electrode 42 is formed of the film of the ionic conductor 40, by providing the ionic conductor 40 only on the side wall of the opening 46, stress generated at the time of metal deposition can be diffused to a side of the interlayer insulating film 45 as well as the cavity 47.

According to the present invention, since metal is deposited on the area having a smaller hardness than the ionic conductive portion at the time of switch-on, structural stress applied to the ionic conductive portion can be further reduced.

According to the present invention, since metal is deposited on the area having a smaller hardness than the ionic conductive portion at the time of switch-on, structural stress applied to the ionic conductive portion can be reduced and a thick metal bridge can be formed. As a result, the on-state is more stabilized.

The switching element according to the present invention can be applied to semiconductor devices such as LSI and semiconductor memories such as DRAM, flash memory and MRAM.

1. A switching element comprising:
a first electrode configured to be available to feed metal ions;
a second electrode;
an ionic conductive portion configured to contact said first electrode and said second electrode, and include an ionic conductor in which said metal ions are movable; and
a buffer portion configured to have a smaller hardness than said ionic conductor, and be located between said first electrode and said second electrode along said ionic conductive portion,
wherein electrical characteristics are switched by depositing or melting metal between said first electrode and said second electrode based on a potential difference between said first electrode and said second electrode.

2. The switching element according to claim 1, wherein said buffer portion includes a porous material.

3. The switching element according to claim 1, wherein said buffer portion is a cavity.

4. The switching element according to claim 1, further comprising:
an insulating film configured to have an opening which reaches said first electrode and said second electrode between said first electrode and said second electrode,
wherein said ionic conductive portion is located on a side wall of said opening.

5. The switching element according to claim 1, wherein said second electrode is disposed on a substrate,
wherein said ionic conductive portion and said buffer portion are disposed on the second electrode, and
wherein said first electrode is disposed on said ionic conductive portion and the buffer portion.

6. The switching element according to claim 1 further comprising:
a third electrode configured to contact said ionic conductive portion, and be available to feed said metal ions,
wherein electrical characteristics are switched by depositing or melting metal between said first electrode and said second electrode based on a potential difference among said first electrode, said second electrode and said third electrode.

7. The switching element according to claim 6, wherein said first electrode and said third electrode are provided on a same plane,
wherein an insulating film having an opening is provided among said first electrode, said third electrode and said second electrode, said opening reaches these three electrodes,
wherein said ionic conductive portion is disposed on a side wall of the opening.

8. The switching element according to claim 6, wherein said second electrode is disposed on said substrate
wherein said ionic conductive portion and said buffer portion are disposed on said second electrode, and
wherein said first electrode and said third electrode are disposed on said ionic conductive portion and said buffer portion.

9. A manufacturing method of a switching element, comprising:
(a) forming a second electrode on a substrate;
(b) forming an opening, substantially vertically to said substrate and partially overlap the second electrode, in an interlayer insulating layer provided so as to cover said substrate and said second electrode;
(c) forming an ionic conductor so as to cover a side wall of said opening;
(d) filling a filling film on an inner side of said ionic conductor; and
(e) forming a first electrode so as to cover said interlayer insulating layer, said ionic conductor and a part of said filling film,
wherein said first electrode is available to feed metal ions,
wherein in ionic conductor, the metal ions are movable, and
wherein said filling film has a smaller hardness than said ionic conductor.

10. The manufacturing method of a switching element according to claim 9, further comprising:
(f) removing said filling film.

11. The manufacturing method of a switching element according to claim 9, wherein said step (e) includes:
(e1) forming a third electrode apart from said first electrode so as to cover said interlayer insulating layer, said ionic conductor and a part of said filling film.

12. The switching element according to claim 4, wherein said second electrode is disposed on a substrate,
wherein said ionic conductive portion and said buffer portion are disposed on the second electrode, and
wherein said first electrode is disposed on said ionic conductive portion and the buffer portion.

13. The switching element according to claim 4, further comprising:
a third electrode configured to contact said ionic conductive portion, and be available to feed said metal ions,
wherein electrical characteristics are switched by depositing or melting metal between said first electrode and said second electrode based on a potential difference among said first electrode, said second electrode and said third electrode.

14. The switching element according to claim 13, wherein said first electrode and said third electrode are provided on a same plane,
wherein an insulating film having an opening is provided among said first electrode, said third electrode and said second electrode, said opening reaches these three electrodes,
wherein said ionic conductive portion is disposed on a side wall of the opening.

15. The switching element according to claim 14, wherein said second electrode is disposed on said substrate
wherein said ionic conductive portion and said buffer portion are disposed on said second electrode, and
wherein said first electrode and said third electrode are disposed on said ionic conductive portion and said buffer portion.
